(19) United States
(12) Patent Application Publication
(10) Pub. No.: US 2016/0024686 A1
(43) Pub. Date: Jan. 28, 2016

(54) METHOD OF DESIGNING A PASSAGE THROUGH A WEIR FOR ALLOWING DILUTIONS OF IMPURITIES

(71) Applicant: SunEdison, Inc., St. Peters, MO (US)

(72) Inventors: Tirumani Swaminathan, Houston, TX (US); Harold Korb, Chesterfield, MO (US)

(21) Appl. No.: 14/341,589

(22) Filed: Jul. 25, 2014

(51) Int. Cl. C30B 15/22; C30B 29/06

(52) U.S. Cl. CPC C30B 15/22; C30B 29/06

(57) ABSTRACT

A method for growing a crystal ingot from a melt in a crystal growing system is provided. The system includes a crucible and a barrier disposed within the crucible. The method includes identifying a Peclet number (Pe) with an advective transport rate that is less than a diffusive transport rate, calculating a cross-sectional area of a passage to be formed in the barrier based on the identified Peclet number to allow outward diffusion of impurities through the passage during growth of the crystal ingot, and growing the crystal ingot using the barrier having the passage formed therein.

### FIELD

This disclosure generally relates to the production of ingots of semiconductor or solar material and more particularly to methods of designing a passage through a weir for increasing the life cycle of the growing process.

### BACKGROUND

In the production of single silicon crystals grown by the Czochralski (CZ) method, polycrystalline silicon is melted within a crucible, such as a quartz crucible, of a crystal pulling device to form a silicon melt. The puller then lowers a seed crystal into the melt and slowly raises the seed crystal out of the melt, solidifying the melt onto the seed crystal. As the ingot is pulled, certain impurities are rejected from the forming ingot structure into the melt immediately adjacent to the ingot, which causes impurity segregation. Impurities include metals and dopant species. The concentration of impurities in the melt immediately adjacent to the ingot increases as ingots are continually pulled from the melt. As a result, the purity of the ingot being pulled decreases as the concentration of the impurities increases, until the process is eventually stopped because the purity of the ingot falls below an acceptable level. To produce single high quality crystal ingots using this method, the temperature and stability of the surface of the melt immediately adjacent to the ingot must be maintained substantially constant, while limiting the impurity concentration adjacent the growing ingot. Prior systems for accomplishing this goal have not been completely satisfactory. Thus, there exists a need for a more efficient and effective system and method to limit temperature and surface disruptions, and the concentration of the impurities in the melt immediately adjacent to the ingot.

This Background section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### BRIEF SUMMARY

In one aspect, a method for growing a crystal ingot from a melt in a crystal growing system is provided. The system includes a crucible and a barrier disposed within the crucible. The method includes identifying a Peclet number (Pe) with an advective transport rate that is less than a diffusive transport rate, calculating a cross-sectional area of a passage to be formed in the barrier based on the identified Peclet number to allow outward diffusion of impurities through the passage during growth of the crystal ingot, and growing the crystal ingot using the barrier having the passage formed therein.

In another aspect, a method for growing crystal ingots from a melt in a crystal growing system is provided. The system includes a crucible and a barrier within the crucible. The barrier has a passage to allow the melt to move therethrough, and the passage has a cross-sectional area configured to allow diffusion of impurities during the growth of the crystal ingots. The method includes designing the passage through the barrier to allow outward diffusion of impurities through the passage during the growth of the crystal ingot, lowering a seed crystal into the melt, raising the seed crystal out of the melt to produce a crystal ingot, separating the crystal ingot from the melt, lowering a second seed crystal into the melt after an ingot exchange time has elapsed following the crystal ingot being separated from the melt, and raising the second seed crystal out of the melt to produce a second crystal ingot.

In yet another aspect, a method for growing a crystal ingot from a melt in a crystal growing system is provided. The system includes a crucible and a barrier within the crucible. The barrier has a passage to allow the melt to move therethrough. The method includes designing the passage through the barrier to allow outward diffusion of impurities through the passage during the growth of the crystal ingot, placing feedstock material into the crucible outward of the barrier, and melting the feedstock material to form the melt to allow movement of the melt inward of the barrier.

Various refinements exist of the features noted in relation to the above-mentioned aspects. Further features may also be incorporated in the above-mentioned aspects as well. These refinements and additional features may exist individually or in any combination. For instance, various features discussed below in relation to any of the illustrated embodiments may be incorporated into any of the above-described aspects, alone or in any combination.

### BRIEF DESCRIPTION OF THE DRAWINGS

FIG. 1 is a cross-sectional view of a crystal growing system in accordance with one embodiment, the crystal growing system including a weir having a passage extending therethrough;

FIG. 2 is a graph plotting the variation of the Peclet number (Pe) with the passage size; and

FIG. 3 is a graph plotting the variation of a characteristic mixing time with a characteristic melt mass for various passage sizes.

Corresponding reference characters indicate corresponding parts throughout the several views of the drawings.

### DETAILED DESCRIPTION

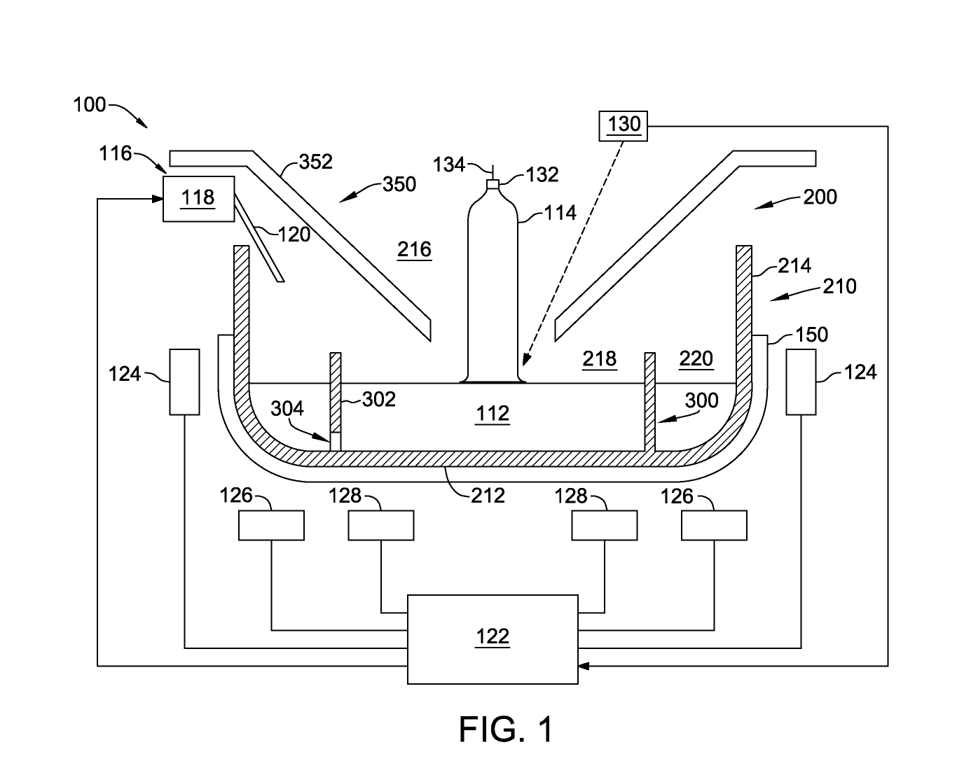

Referring to FIG. 1, a crystal growing system is shown schematically and is indicated generally at 100. The crystal growing system 100 is used to produce a single crystal ingot by a Czochralski method. As discussed herein, the system is described in relation to the continuous Czochralski method of producing single crystal ingots, though a batch process may be used. However, the system disclosed herein may also be used to produce multi-crystalline ingots, such as by a directional solidification process.

During the continuous Czochralski method of producing single crystal ingots, feedstock is supplied to and melted in a radially outward area of the crucible, while the crystal ingot is simultaneously being grown from the melt. One or more silica barriers or weirs are located between where the feedstock is supplied and where the crystal ingot is pulled, to form a crucible assembly. These weir(s) create multiple zones within the crucible assembly and inhibit solid or unmelted feedstock from passing into an area that is immediately adjacent to the growing crystal. Pieces of the solid feedstock in the inner area or zone located within the melt are colloquially referred to as “fish.”

By inhibiting the melt entering the inner zone, the weir also inhibits movement of the rejected impurities outward of the weir, which causes the impurities to become concentrated within the area immediately adjacent the growing ingot. Traditionally, the size of the inner zone was maximized (e.g., by increasing the depth of the melt) to increase the amount of impurities that could be contained within the melt in the inner zone before the purity of the ingot dropped below an acceptable level. However, increasing the size of the inner zone by increasing the melt depth also causes an increase in the amount of interstitial oxygen because higher surface areas of quartz results in more oxygen being dissolved into the inner zone during the process.

Further, the size of the crucible limits the size of the weir that may be used and the overall volume of the melt in the inner zone. These dimensional limitations determine the number of crystals that may be grown from a single melt. The run time or pull time required for the purity level of the ingot to fall below an acceptable level is inversely related to the volume of the melt in the inner zone. As the volume of the inner zone increases, the concentration of impurities decreases and allows a longer run time before the acceptable level of impurities is exceeded. However, use of the embodiments disclosed herein allows more ingots to be grown from a single melt because the impurities do not concentrate as quickly within the inner zone as compared to conventional systems.

The crystal growing system 100 includes a crucible support or susceptor 150 supporting a crucible assembly 200 that contains silicon melt 112 from which an ingot 114 is being pulled by a puller or pull system 134 e.g., a cable. A seed crystal 132 is attached to a portion of puller 134 disposed over melt 112. The puller 134 provides movement of seed crystal 132 in a direction perpendicular to the surface of melt 112 allowing the seed crystal to be lowered down toward or into the melt, and raised up or out of the melt.

During the crystal pulling process, the seed crystal 132 is lowered by the puller 134 into the melt 112 and then slowly raised or pulled from the melt. As seed crystal 132 is slowly raised from melt 112, the single crystal ingot 114 is formed and certain impurities are rejected into the surrounding melt. The puller 134 has several seed crystals 132, which allows multiple ingots 114 to be pulled from the melt 112 during the process. Thus, as each ingot 114 is pulled from the melt 112, the concentration of impurities in the melt increases. To produce a high quality ingot 114, the melt 112 in an area adjacent to seed crystal 132/ingot 114 must be maintained at a substantially constant temperature and substantially free from surface disruptions, and foreign solid particles and impurities must be minimized.

To limit surface disturbances, temperature fluctuations, and foreign solid particles in the area immediately adjacent to seed crystal 132/ingot 114, the crucible assembly 200 includes a crucible 210 and weir 300. The crucible 210 has a base 212 and a sidewall 214. The sidewall 214 of the crucible 210 is located approximately concentric with the cable of the puller 134. The sidewall 214 extends around the circumference of the base 212 to form a cavity 216 for containing the melt 112.

The weir 300 is disposed within the cavity 216 along the base 212 at a location inward from the sidewall 214. As disclosed, the weir 300 is a single cylindrical melt flow barrier or pipe that separates the area within the cavity 216 into an inner zone 218 and an outer zone 220. In some embodiments, the weir is an internal crucible. In other embodiments, the weir may include multiple barriers in the form of pipes, crucibles, or combinations thereof. In these embodiments, the passages through each barrier are sized to have a cross-sectional area that promotes effective participation in the dilution process of the impurities.

The inner zone 218 is an area defined by the base 212 and an area inward of the weir 300, from which the ingot is pulled. This inner zone 218 is the area immediately adjacent the growing ingot 114, into which impurities are rejected as ingots are pulled from the melt 112.

The outer zone 220 is an area defined by the base 212, the sidewall 214, and the weir 300. The weir 300 inhibits movement of the melt 112 from the outer zone 220 to the inner zone 218. The weir 300 includes a body 302 having at least one notch or weir passage 304 extending therethrough to allow the melt 112 to move inward of the weir and impurities to move outward of the weir. Thus, the cross-sectional area of the passage 304 of this embodiment is designed to allow diffusion of impurities during the growth of the crystal ingot 114. The weir passage 304 is disposed along a lower section of weir 300 at an elevation below the ultimate melt depth to allow consistent melt levels inward of the weir. In some embodiments, the weir 300 may have multiple passages 304.

In many instances, the bottoms of the weirs do not form perfect barriers with the crucibles to prevent the flow of the unmelted feedstock. As a result, the unmelted or solid particles of feedstock material pass through small gaps between the bottom of the weirs and the crucible. The passage of the solid particle into an area adjacent to a forming crystal ingot greatly increases the risk of the ingot being hit and having its crystalline structure disrupted (sometimes called loss-of-structure or LOS). In some embodiments, the weir 300 is bonded to the base 212. In some embodiments, the weir 300 has a bottom edge shaped to conform to the contacting points of the interior of the crucible 210 and is fire polished.

The weir 300 limits movement of melt 112 between the outer melt portion or outer zone 220 and the inner melt portion or inner zone 218. The passage 304 permits controlled movement of the melt 112 between the outer zone 220 and the inner zone 218 through the lower section of the weir 300. By inhibiting or limiting movement of the melt 112 between the zones 218, 220, the feedstock material 116 is retained in the outer zone while heat is applied to it and melts it. Thus, the melt 112 in the outer zone 220 is liquefied before it moves into the inner zone 218. As a result, unmelted feedstock material is inhibited from passing into the inner zone 218 and causing a dislocation in the ingot. Unmelted feedstock may disturb or negatively affect the structural integrity and the crystal structure of the ingot being formed.

Further, inhibiting movement of the melt 112 between the zones to through the passage 304 allows the surface of the melt in the inner zone 218 to remain relatively undisturbed. The weir 300 substantially prevents disturbances in the outer zone 220 from disrupting the surface of the melt 112 in the inner zone by substantially containing the thermal and mechanical energy waves produced by the disturbances in the outer zone. The disturbances are also inhibited from passing into the inner zone 218 by the location of the passage 304. The passage 304 is disposed below the melt top level contact to allow movement of the melt 112 into the inner zone 218 without disrupting the surface stability of the inner zone.

The movement of melt 112 is substantially limited to the location of the passage 304. Placing the passage 304 along the lower section of weir 300 confines the movement of melt 112 to along the bottom of the crucible assembly 200. As a result, any movement of melt 112 into the inner zone 218 is at a location beneath or directly opposite to that of the top of the melt 112, where ingot 114 is being pulled. This confinement of the melt movement limits surface disruptions and temperature fluctuations along the top of the inner melt portion of the melt 112, which limit dislocations in the forming ingot 114.

In addition, the temperature of the melt increases as the melt passes from the outer zone to the inner zone. By the time the melt reaches the inner zone, the melt is substantially equivalent in temperature to the melt already in the inner zone.

Solid feedstock material 116 may be placed into the outer zone 220 from feeder 118 through feed tube 120. The feedstock material 116 is at a much lower temperature than the surrounding melt 112 and absorbs heat from the melt as the feedstock material's temperature rises, and as the solid feedstock material liquefies in the outer zone to form an outer melt portion. As the solid feedstock material 116 (sometimes referred to as “cold feedstock”) absorbs energy from melt 112, the temperature of the surrounding melt falls proportionately to the energy absorbed.

The amount of feedstock material 116 added is controlled by feeder 118, which is responsive to activation signals from a controller 122. The amount of cooling of the melt 112 is precisely determined and controlled by controller 122. Controller 122 may add feedstock material 116 to adjust the temperature and the mass of the melt 112. The addition of feedstock material 116 may be based on the mass of the silicon in the crucible, e.g., by measuring the weight or measuring liquid height of the melt.

As solid feedstock material 116 is added to melt 112, the surface of the melt 112 in the outer zone 220 may be disturbed. This disturbance could affect the ability of the silicon atoms of the melt 112 to properly align with the silicon atoms of the seed crystal 132. However, as discussed above, the weir 300 inhibits inward propagation of these disturbances.

Heat is supplied to crucible assembly 200 by one or more heaters 124, 126, and 128 arranged at suitable positions about the crucible assembly. Heat from heaters 124, 126, and 128 initially melt the solid feedstock material 116 and then maintains melt 112 in a liquefied state providing suitable growth conditions for the ingot 114.

Heaters 124, 126, and 128 are suitably resistive heaters and may be coupled to controller 122. The controller 122 controls electric current provided to the heaters, to control heater power delivery, and the feedstock material to thereby control the temperature of the melt. The controller 122 is also capable of simultaneously supplying feedstock material 116 while the seed crystal 132 is raised from the melt 112, growing the ingot 114.

A sensor 130, such as a pyrometer or like temperature sensor, provides a continuous measurement of the temperature of melt 112 at the crystal/melt interface of the growing single crystal ingot 114. Sensor 130 also may be configured to measure the temperature of the growing ingot. Sensor 130 is communicatively coupled with controller 122. Additional temperature sensors may be used to measure and provide temperature feedback to the controller with respect to points that are critical to the melting of the feedstock material or in controlling the growing ingot. While a single wire is shown for clarity, one or more temperature sensor(s) may be linked to the controller by multiple wires or a wireless connection, such as by an infra-red data link or another suitable means.

The crystal growing system 100 of this embodiment includes shield 350 adjacent crucible assembly 200. The shield 350 has a conical member 352. However, any suitable horizontally rotated cross-sectional shape that separates the melt 112 from an upper portion of the system 100 and has a central opening to allow the ingot 114 to be pulled therethrough may be used.

The crystal growing system 100 may include an evaporative oxygen removal subsystem that uses gas flow to reduce the overall level of oxygen within the system. The crucible 210 and the weir 300 are suitably made of quartz, and the melt 112 and feedstock 116 are silicon. In these embodiments, the silicon melt 112 is corrosive and could cause cut-through of the quartz of the crucible and weir at low pressures that would negatively limit the total run time of the system. To prevent excessive erosion of the crucible and weir that would limit the total run time, oxygen is biased upwards by delivering a supply of argon. The higher oxygen content in the melt surface then limits the quartz erosion rate. The higher pressures reduce the velocity of the argon within the system, resulting in a decrease in silicon monoxide being evaporated from the melt surface. Less silicon monoxide is then carried into the exhaust lines preventing the premature blocking of the exhaust lines and early run termination.

A method of one embodiment for designing the size or cross-sectional area of the notch or passage through a weir or barrier for use in a crucible for growing a crystal ingot from a melt during a continuous Czochralski process is now disclosed. The size or cross-sectional area of the passage is based on quantifying liquid silicon flow characteristics and a desired dilution of the specified impurities. Thus, the cross-sectional area of the passage is based on impurity contamination, and not minimizing the gaseous bubbles in the melt, as in the prior art.

As discussed above, the weir may have one or more passages extending therethrough. The cross-sectional area as discussed herein, unless otherwise noted, is the total cross-sectional area of all passages in the weir. The size of the cross-sectional area of the passage is designed to allow diffusion of impurities during the growth of the crystal ingot. The cross-sectional area (l²) is based on the length (l) of a side of a square notch. However, the passage may have other cross-sectional shapes.

First, a Peclet number (Pe) with an advective transport (inward flow or convection) rate that is less than a diffusive transport (outward flow or invection) rate is identified. Then, a cross-sectional area of the passage that allows diffusion of impurities during the growth of the crystal ingot is calculated. Before calculating the cross-sectional area, a radius (R_{c}) of the crystal ingot to be produced and a thickness (L) of the barrier at a location through which the passage is to be located is identified. Further, the density of the melt (ρₘ) from which the ingot will be grown, the density of the solid feedstock material (ρ_{c}) to be placed in the crucible outward of the barrier, an effective diffusivity of the melt (D_{eff}), and a vertical rate of solidification (s) based on the radius of the crystal ingot to be produced is determined. Then, the cross-sectional area of the passage (l²) is calculated based on density of the melt (ρₘ), density of the solid feedstock material (ρ_{c}), thickness of the barrier (L), effective diffusivity of the melt (D_{eff}), radius of the crystal ingot (R_{c}), and vertical rate of solidification (s) using the equation:

$${l}^{2} = \frac{{ρ}_{m} π {R}_{c}^{2} Ls}{{ρ}_{c} {D}_{eff} Pe} .$$

In some embodiments, the Peclet number (Pe) may be chosen to be between 0.5 and 1.0. Thus, in some embodiments, the cross-sectional area of the passage (l²) is calculated based on the following constraint:

$$\frac{{ρ}_{m} π {R}_{c}^{2} Ls}{{ρ}_{c} {D}_{eff}} \leq {l}^{2} \leq 2 ( \frac{{ρ}_{m} π {R}_{c}^{2} Ls}{{ρ}_{c} {D}_{eff}} )$$

This constraint is also referred to herein as a growth constraint because it represents a constraint for determining the cross-sectional area of the passage (l²) based on impurity diffusion and melt flow characteristics of the melt while an ingot is being grown.

In some embodiments, the effective diffusivity of the liquid melt (D_{eff}) is about 0.1 cm^{/}s. In some embodiments, the density of the melt (ρₘ) is about 2.57 g/cm³. In some embodiments, the density of the solid feedstock material (ρ_{c}) is about 2.329 g/cm³.

Some embodiments of this method may include designing multiple passages to limit passage of solid feedstock material into the inner zone. In this embodiment, a maximum cross-sectional area of a single passage that provides an effective barrier is identified (i.e., a cross-sectional area above which the barrier will no longer effectively restrict solid feedstock material 116 from reaching the inner melt zone). The number of passages in the barrier is calculated by dividing the total calculated cross-sectional area of the passage (l²) by the maximum cross-sectional area of an effective barrier passage. The number of passages in the barrier is then rounded up to the next whole number. Finally, an individual cross-sectional area of each of the multitude of passages is calculated by dividing the total cross-sectional area of the passage (l²) by the next whole number.

Referring again to FIG. 1, in a method of one embodiment for growing a single crystal ingot 114 in a crucible assembly 200 having a crucible 210 with a base 212 and a sidewall 214 that form a cavity 216, a barrier or weir 300 is placed in the cavity 216 of the crucible 210 to separate the melt 112 into an inner melt portion in an inner zone 218 and an outer melt portion in an outer zone 220. The inner melt portion is inward of weir 300 and is adjacent to the seed crystal 132/ingot 114. The outer melt portion is outward of weir 300. The weir 300 includes a body 302 and a passage 304 therethrough. In some embodiments, the weir is a cylindrical pipe. In some embodiments, the weir is a second, internal crucible. In other embodiments, the weir is a plurality of cylindrical pipes, internal crucibles, or a combination of thereof.

The cross-sectional area (l²) of the passage allows diffusion of impurities during the growth of the crystal ingot, as discussed above.

Feedstock material 116 is placed in the outer zone 220. Heaters 124, 126 and 128 are placed adjacent to the crucible assembly 200 to provide heat to the crucible and barrier for liquefying or melting the feedstock material 116, forming a melt 112. Once liquefied, the melt 112 is able to move from the outer zone 220 into the inner zone 218, but the movement of the melt is limited to through passage 304.

The seed crystal 132 is lowered into and then slowly raised out of the melt 112 to grow the ingot from the seed crystal. As the seed crystal 132 is slowly raised, silicon atoms from the melt 112 align with and attach to the silicon atoms of the seed crystal 132 allowing the ingot to grow larger and larger as a monocrystal. The raising of the silicon atoms from the melt 112 causes them to cool and solidify, producing crystal ingot. The raising of the seed crystal is performed simultaneously with placing the feedstock material into the crucible. The crystal ingot is separated from the melt.

In some embodiments, a second seed crystal is lowered into the melt and raised out of the melt to produce a second crystal ingot after production of the crystal ingot. In these embodiments, the time between successive crystals is called ingot exchange time. In some embodiments, the ingot exchange time is based on a characteristic mixing time that is a function of the melt characteristics. The characteristic mixing time is a time scale used to determine or approximate an amount of time required to allow the melt to become substantially mixed and the impurities within the melt to be diluted across the entire volume of the melt. In some embodiments, the characteristic melting time represents the amount of time required for the impurity concentration within the inner melt portion or inner zone 218 (as measured at the beginning of the time period) to be reduced by a factor of

$$\frac{1}{e} .$$

After approximately 5 characteristic mixing times have elapsed, the impurity concentration within the melt is substantially uniform between the inner melt portion or inner zone 218 and the outer melt portion or outer zone 220.

In some embodiments, the crystal growing process is carried out such that the ingot exchange time is greater than the characteristic mixing time. More specifically, following the removal of a first crystal ingot from the crucible, a second seed crystal is lowered towards the melt after a sufficient amount of time has passed for impurities inward of the barrier to be diluted across the entire volume of the melt. In some embodiments, the amount of time (i.e., the ingot exchange time) is at least about two times the characteristic mixing time, more suitably at least about three times the characteristic mixing time, and, even more suitably, at least about four times the characteristic mixing time.

In some embodiments, the characteristic mixing time (τ) is calculated using the equation:

$$τ = \frac{ML}{{ρ}_{m} {D}_{eff} {l}^{2}}$$

where M is total mass of the melt, L is the thickness of the internal barrier through which the passage extends, D_{eff} is the effective diffusivity of the liquid melt, ρₘ is the density of the melt, and l² is the cross-sectional area of the passage. Therefore, to calculate the characteristic mixing time (τ), the thickness (L) of the internal barrier at the location through which the passage is located is identified. Further, total mass of the melt (M), the density of the melt (ρₘ), and the effective diffusivity of the liquid melt (D_{eff}) are determined.

In another embodiment, the characteristic mixing time (τ) is used to determine the cross-sectional area of the passage. More specifically, the ingot exchange time (T) is a fixed parameter (e.g., 4 hours), and the cross-sectional area of the passage (l²) is selected such that the characteristic mixing time (τ) is less than the ingot exchange time. In such embodiments, a desired characteristic mixing time (τ) may be identified based upon the ingot exchange time (T). For example, the desired characteristic mixing time (τ) may be less than about one-half the ingot exchange time (T), more suitably less than about one-third the ingot exchange time (T), and, even more suitably, less than about one-fourth the ingot exchange time (T). In other words, the desired characteristic mixing time is identified such that at least one characteristic mixing time will elapse during the ingot exchange time to allow the impurity concentration within the inner melt portion or inner zone 218 to decrease to an acceptable level. The cross-sectional area of the passage (l²) may be calculated using the constraint:

$${l}^{2} \geq \frac{ML}{{ρ}_{m} {D}_{eff} kT}$$

where k is a coefficient less than one (e.g., ½, ⅓, ¼), T is the ingot exchange time, and M, L, D_{eff}, and ρₘ have the same values as described above. This constraint is also referred to herein as a non-growth constraint because it represents a constraint for determining the cross-sectional area of the passage (l²) based on impurity diffusion and melt flow characteristics of the melt while no ingot is being grown.

In some embodiments, the cross-sectional area of the passage (l²) is determined based on both a growth constraint and a non-growth constraint. In such embodiments, the cross-sectional area of the passage (l²) may be determined by identifying a growth constraint based on impurity diffusion and melt flow characteristics of the melt while an ingot is being grown, identifying a non-growth constraint based on impurity diffusion and melt flow characteristics of the melt while no ingot is being grown from the melt, and determining a cross-sectional area of the passage that satisfies both the growth constraint and the non-growth constraint. In some embodiments, the growth constraint is equal to:

$$\frac{{ρ}_{m} π {R}_{c}^{2} Ls}{{ρ}_{c} {D}_{eff}} \leq {l}^{2} \leq 2 ( \frac{{ρ}_{m} π {R}_{c}^{2} Ls}{{ρ}_{c} {D}_{eff}} ) ,$$

and the non-growth constraint is equal to:

$${l}^{2} \geq \frac{ML}{{ρ}_{m} {D}_{eff} kT} .$$

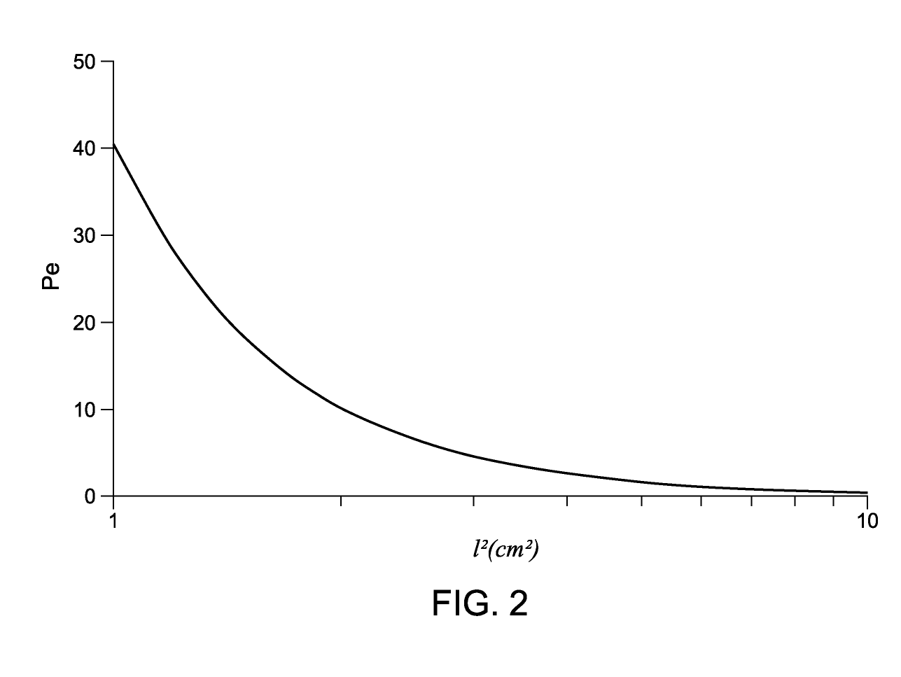

FIG. 2 shows the effect that various cross-sectional areas of the passage (l²) have on the Peclet number (Pe) for a silicon ingot growth process having a quartz barrier with a thickness (L) of about 1.27 cm, a vertical rate of solidification (s) of about 1.6 mm/minute, and a crystal radius (R_{c}) of about 205 mm. The effective diffusivity of a silicon melt (D_{eff}) is about 0.1 cm²/s, the density of liquid silicon (ρₘ) is about 2.57 g/cm², and the density of solid silicon (ρ_{c}) is about 2.329 g/cm².

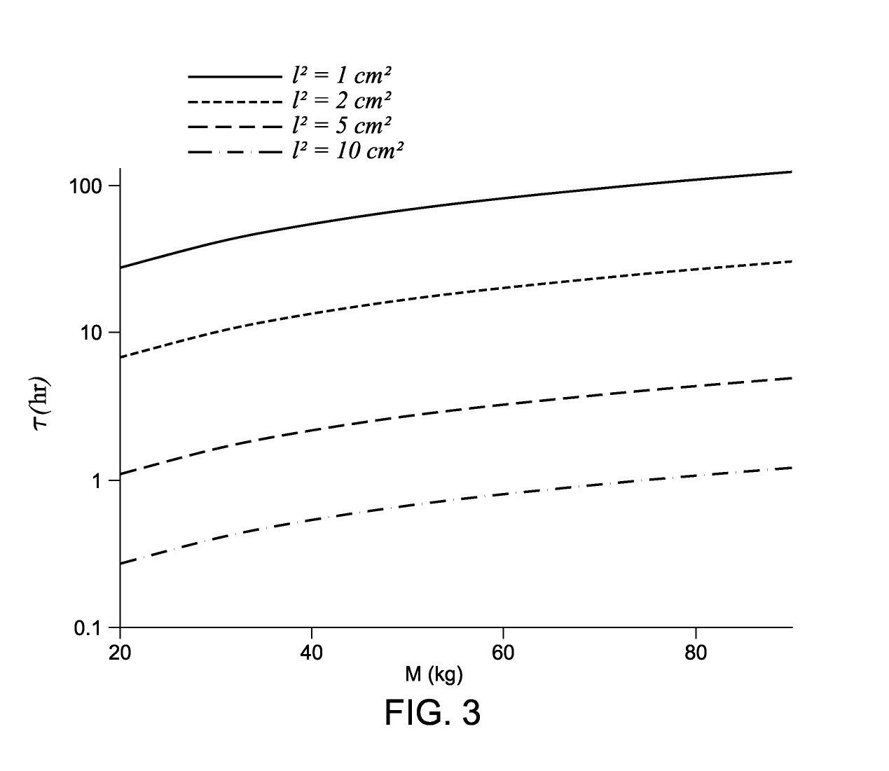

FIG. 3 shows the effect that various cross-sectional areas of the passage (l²) have on the characteristic mixing time (τ) for a variety of characteristic melt masses (M) in a silicon growth process having a barrier with a thickness of about 1.27 cm.

Use of the above embodiments significantly improves the lifespan of the system. Thus, the runtime of the furnace is increased because impurities are dispersed across the entire volume of the melt, and not concentrated within the melt in the inner zone. Further, the weir and crucible do not have to be replaced as often. An additional advantage is that there is no substantial change in the oxygen impurity in the ingot since the fluid mechanical characteristics in the inner zone are not changed. Another advantage is that the efficiency and runtime of the overall production of the crystal forming system is increased, while the overall operational costs are lowered.

When introducing elements of the present invention or the embodiment(s) thereof, the articles “a”, “an”, “the” and “said” are intended to mean that there are one or more of the elements. The terms “comprising”, “including” and “having” are intended to be inclusive and mean that there may be additional elements other than the listed elements. The use of terms indicating a particular orientation (e.g., “top”, “bottom”, “side”, etc.) is for convenience of description and does not require any particular orientation of the item described.

As various changes could be made in the above constructions and methods without departing from the scope of the invention, it is intended that all matter contained in the above description and shown in the accompanying drawing(s) shall be interpreted as illustrative and not in a limiting sense.

What is claimed is:

1. A method for growing a crystal ingot from a melt in a crystal growing system, the system including a crucible and a barrier disposed within the crucible, the method comprising:
identifying a Peclet number (Pe) with an advective transport rate that is less than a diffusive transport rate;
calculating a cross-sectional area of a passage to be formed in the barrier based on the identified Peclet number to allow outward diffusion of impurities through the passage during growth of the crystal ingot; and
growing the crystal ingot using the barrier having the passage formed therein.

2. The method of claim 1, wherein the step of calculating the cross-sectional area of the passage (l²) is based on density of the melt (ρₘ), a density of solid feedstock (ρ_{c}) added to the melt, a thickness of the barrier (L), an effective diffusivity of the melt (D_{eff}), a radius of the crystal ingot (R_{c}) grown from the melt, and a vertical rate of solidification (s) of the crystal ingot.

3. The method of claim 2, wherein the step of calculating the cross-sectional area of the passage (l²) is calculated using the equation:
$${l}^{2} = \frac{{ρ}_{m} π {R}_{c}^{2} Ls}{{ρ}_{c} {D}_{eff} Pe} .$$

4. The method of claim 3, further comprising the steps of:
determining the density of the melt (ρₘ) to be located in the crucible;
determining the density of the solid feedstock (ρ_{c}) to be added to the melt;
identifying the thickness (L) of the barrier through which the passage is to be located;
determining the effective diffusivity of the melt (D_{eff});
identifying the radius (R_{c}) of the crystal ingot to be grown; and
determining the vertical rate of solidification s) of the crystal ingot based on the radius of the crystal ingot to be produced.

5. The method of claim 2, wherein the melt is a silicon melt, and the effective diffusivity of the liquid melt (D_{eff}) is about 0.1 cm²/s, the density of the melt (ρₘ) is about 2.57 g/cm³, and the density of the solid feedstock material (ρₐ) is about 2.329 g/cm³.

6. The method of claim 1, further comprising the step of identifying a maximum cross-sectional area of a single passage that provides an effective barrier.

7. The method of claim 6, further comprising calculating a minimum number of passages in the barrier by dividing the calculated cross-sectional area of the passage (l²) by the maximum cross-sectional area.

8. The method of claim 7, further comprising calculating a cross-sectional area of each of a multitude of passages by dividing the calculated cross-sectional area of the passage (l²) by the minimum number of passages.

9. The method of claim 1, wherein the Peclet number (Pe) is between 0.5 and 1.0.

10. The method of claim 1, further comprising:
identifying a non-growth constraint on the cross-sectional area of the passage (l²) based on impurity diffusion and melt flow characteristics of the melt while no ingot is being grown from the melt; and
determining the cross-sectional area of the passage (l²) based on the identified Peclet number and the non-growth constraint.

11. A method for growing crystal ingots from a melt in a crystal growing system, the system including a crucible and a barrier within the crucible, wherein the barrier has a passage to allow the melt to move therethrough, the passage having a cross-sectional area configured to allow diffusion of impurities during the growth of the crystal ingots, the method comprising:
designing the passage through the barrier to allow outward diffusion of impurities through the passage during the growth of the crystal ingot;
lowering a seed crystal into the melt;
raising the seed crystal out of the melt to produce a crystal ingot;
separating the crystal ingot from the melt;
lowering a second seed crystal into the melt after an ingot exchange time has elapsed following the crystal ingot being separated from the melt; and
raising the second seed crystal out of the melt to produce a second crystal ingot.

12. The method of claim 11, wherein designing the passage through the barrier includes:
identifying a growth constraint on the cross-sectional area of the passage based on impurity diffusion and melt flow characteristics of the melt while an ingot is being grown;
identifying a non-growth constraint on the cross-sectional area of the passage based on impurity diffusion and melt flow characteristics of the melt while no ingot is being grown from the melt; and
determining a cross-sectional area of the passage that satisfies both the growth constraint and the non-growth constraint.

13. The method of claim 12, wherein the growth constraint on the cross-sectional area of the passage (l²) is based on a density of the melt (ρₘ), a density of solid feedstock (ρ_{c}) added to the melt, a thickness of the barrier (L), an effective diffusivity of the melt (D_{eff}), a radius of the crystal ingot (R_{c}), and a vertical rate of solidification (s) of the crystal ingot.

14. The method of claim 13, wherein the growth constraint on the cross-sectional area of the passage (l²) is
$$\frac{{ρ}_{m} π {R}_{c}^{2} Ls}{{ρ}_{c} {D}_{eff}} \leq {l}^{2} \leq 2 ( \frac{{ρ}_{m} π {R}_{c}^{2} Ls}{{ρ}_{c} {D}_{eff}} )$$

15. The method of claim 12, wherein the non-growth constraint is based on a total mass of the melt (M), a thickness of the barrier (L), an effective diffusivity of the liquid melt (D_{eff}), a density of the melt (ρₘ), and the ingot exchange time (T).

16. The method of claim 15, wherein the non-growth constraint on the cross-sectional area of the passage (l²) is
$${l}^{2} \geq \frac{ML}{{ρ}_{m} {D}_{eff} kT} ,$$
where k is a coefficient less than one.

17. A method for growing a crystal ingot from a melt in a crystal growing system, the system including a crucible and a barrier within the crucible, wherein the barrier has a passage to allow the melt to move therethrough, the method comprising:
designing the passage through the barrier to allow outward diffusion of impurities through the passage during the growth of the crystal ingot;
placing feedstock material into the crucible outward of the barrier; and
melting the feedstock material to form the melt to allow movement of the melt inward of the barrier.

18. The method of claim 17, further comprising the steps of lowering a seed crystal into the melt and raising the seed crystal out of the melt to produce a crystal ingot.

19. The method of claim 18, wherein the raising of the seed crystal is performed simultaneously with placing the feedstock material into the crucible.

20. The method of claim 18, further comprising the steps of lowering a second seed crystal into the melt and raising the second seed crystal out of the melt to produce a second crystal ingot after production of the crystal ingot.

21. The method of claim 20, further comprising the step of waiting an amount of time in between the raising of the seed crystal and the lowering of the second seed crystal, wherein the amount of time is based on a characteristic mixing time (τ) of the melt.

22. The method of claim 21, further comprising the step of calculating the characteristic mixing time (τ) based on a total mass of the melt (M), a thickness of the internal barrier (L) through which the passage extends, an effective diffusivity of the liquid melt (D_{eff}), a density of the melt (ρₘ), and a cross-sectional area of the passage (l²).

23. The method of claim 22, wherein the step of calculating the characteristic mixing time (τ) is calculated using the equation:
$$τ = \frac{ML}{{ρ}_{m} {D}_{eff} {l}^{2}} .$$
